(19) United States
(12) Patent Application Publication
(10) Pub. No.: US 2018/0358212 A1
(43) Pub. Date: Dec. 13, 2018

(54) SYSTEM CONFIGURED FOR SPUTTER DEPOSITION ON A SUBSTRATE, SHIELDING DEVICE FOR A SPUTTER DEPOSITION CHAMBER, AND METHOD FOR PROVIDING AN ELECTRICAL SHIELDING IN A SPUTTER DEPOSITION CHAMBER

(71) Applicant: Applied Materials, Inc., Santa Clara, CA (US)

(72) Inventors: Thomas Werner ZILBAUER, Gauting (DE); Uwe HENKEL, Dietzenbach/Steinberg (DE); Johannes THIEL, Mainhausen (DE); Kamal EL ZAAR, Mittelbuchen/Hanau (DE); Stefan KELLER, Mainaschaff (DE)

(21) Appl. No.: 15/771,803

(22) PCT Filed: Dec. 9, 2015
(86) PCT No.: PCT/IB2015/002317

§ 371 Date: Apr. 27, 2018

(51) Int. Cl. H01J 37/34

(52) U.S. Cl. CPC H01J 37/3441

(57) ABSTRACT

The present disclosure provides a system configured for sputter deposition on a substrate. The system includes a sputter deposition chamber having a processing zone, one or more sputter deposition sources arranged at a first side of the processing zone, and a shielding device arranged at a second side of the processing zone, wherein the shielding device includes a frame assembly mounted to the sputter deposition chamber and one or more conductive sheets detachably mounted on the frame assembly, wherein the one or more conductive sheets provide a surface arranged along the processing zone.

### FIELD

Embodiments of the present disclosure relate to a system configured for sputter deposition on a substrate, a shielding device for a sputter deposition chamber, and a method for providing an electrical shielding in a sputter deposition chamber. Embodiments of the present disclosure particularly relate to an electrical shielding used in AC sputtering or sputtering having an AC component, and specifically RF sputtering.

### BACKGROUND

Techniques for layer deposition on a substrate include, for example, sputter deposition, thermal evaporation, and chemical vapor deposition (CVD). A sputter deposition 20 process can be used to deposit a material layer, e.g., a film, on the substrate, such as a layer of an insulating material. During the sputter deposition process, a target having a target material to be deposited on the substrate is bombarded with ions generated in a plasma zone to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxinitride of the target material on the substrate.

During the sputter deposition process, for example, in the manufacture of displays, touch screen panels or thin film batteries, non-uniform film deposition or arcing can occur due to potential differences within a vacuum processing chamber, such as a sputter deposition chamber. Arcing can damage, for example, a substrate carrier and/or the substrate. Further, arcing can affect homogeneity and/or purity of the material layer deposited on the substrate. Moreover, a presence of electrical pathways from and returning to an AC power source to structures, for example, grounded structures, within the vacuum processing chamber can lead to the formation of parasitic plasma. Parasitic plasma can reduce an efficiency of the sputter deposition process, for example, a sputtering power and a deposition rate on the substrate surface. Further, a quality of the material layer, for example, a homogeneity and/or purity, can be reduced.

Further, an efficiency of a sputter deposition system can be dependent on its ability to generate homogenous film deposition with respect to homogeneity of film properties across the area of the substrate and/or across the film thickness. Geometrical and electrical homogeneity within space, e.g., with respect to a steric arrangement of components defining the deposition zone in the sputter deposition system, and within time are beneficial, e.g., along the transport direction of the substrate such as from deposition compartment to deposition compartment within an in line deposition system.

In view of the above, new systems configured for sputter deposition on a substrate, shielding devices for a sputter deposition chamber, and methods for providing an electrical shielding in a sputter deposition chamber, that overcome at least some of the problems in the art are beneficial. The present disclosure particularly aims to provide a system, a shielding device, and a method that can reduce or even prevent the occurrence of arcing and/or parasitic plasmas in a sputter deposition chamber.

### SUMMARY

In light of the above, a system configured for sputter deposition on a substrate, a shielding device for a sputter deposition chamber, and a method for providing an electrical shielding in a sputter deposition chamber are provided. Further aspects, benefits, and features of the present disclosure are apparent from the claims, the description, and the accompanying drawings.

According to an aspect of the present disclosure, a system configured for sputter deposition on a substrate is provided. The system includes a sputter deposition chamber having a processing zone, one or more sputter deposition sources arranged at a first side of the processing zone, and a shielding device arranged at a second side of the processing zone, wherein the shielding device includes a frame assembly mounted to the sputter deposition chamber and one or more conductive sheets detachably mounted on the frame assembly, and wherein the one or more conductive sheets provide a surface arranged along the processing zone.

According to another aspect of the present disclosure, a shielding device for a sputter deposition chamber is provided. The shielding device includes a frame assembly configured to be mounted to the sputter deposition chamber and along a processing zone in the sputter deposition chamber, and one or more conductive sheets detachably mounted on the frame assembly, wherein the one or more conductive sheets are configured to face towards the processing zone.

According to a further aspect of the present disclosure, a method for providing an electrical shielding in a sputter deposition chamber is provided. The method includes providing an equipotential surface along a processing zone in the sputter deposition chamber using one or more conductive sheets detachably mounted on a frame assembly.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic top view of a system configured for sputter deposition on a substrate according to embodiments described herein;

FIG. 1B shows a schematic top view of a shielding device for a sputter deposition chamber according to embodiments described herein;

FIG. 2 shows a schematic top view of a system configured for sputter deposition on a substrate according to further embodiments described herein;

FIG. 3 shows a perspective front view of a shielding device for a sputter deposition chamber according to embodiments described herein;

FIG. 4 shows a perspective rear view of the shielding device of FIG. 3;

FIG. 5 shows a schematic view of a frame assembly of a shielding device according to embodiments described herein;

FIG. 6 shows a cross-sectional schematic view of the frame assembly of FIG. 5;

FIG. 7 shows a schematic view of a grounding device attached to the shielding device according to embodiments described herein;

FIGS. 8A and 8B show schematic views of a mounting structure of the shielding device according to embodiments described herein;

FIG. 9 shows schematic views of a mounting device of the shielding device according to embodiments described herein; and

FIG. 10 shows a flow chart of a method for providing an electrical shielding in a sputter deposition chamber according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Systems configured for sputter deposition on a substrate can be used, for example, in the manufacture of displays or components thereof, such as thin film transistors. During the sputter deposition process, arcing and/or parasitic plasmas can occur. Arcing and parasitic plasmas can affect at least one of process stability, process efficiency and process quality of the sputter deposition process.

In particular, arcing can occur due to potential differences within the sputter deposition chamber. Arcing can damage, for example, the substrate and/or a carrier having the substrate positioned thereon. Further, arcing can affect at least one of homogeneity and purity of the material layer deposited on the substrate. Moreover, electrical pathways from an AC power source to structures, for example, grounded structures, within the sputter deposition chamber can be present that can lead to the formation of parasitic plasma. Parasitic plasma can reduce an efficiency of the sputter deposition process such as a deposition rate on the substrate surface. Further, a quality of the material layer, for example, a homogeneity and/or purity, can be reduced.

Moreover, potential differences due to non-homogenous AC feed-in and AC return paths result in non-homogenous plasma conditions. This can result in non-uniform film deposition conditions and in a film with decreased uniformity with respect to its envisaged properties such as mechanical, optical, electrical, and/or chemical properties.

The present disclosure provides a shielding device, such as an electrical shielding, mounted along at least a portion of a processing zone of a sputter deposition chamber acting as a defined and effective anode for the sputter target operated as a cathode, due to its defined electrical equipotential surface in the AC environment. The electrical shielding of the shielding device is provided by one or more conductive sheets detachably mounted on a frame assembly. The one or more conductive sheets provide a flat equipotential surface or area. The occurrence of arcing and/or parasitic plasmas during a sputter deposition process can be reduced or even avoided. In particular, damage to the substrate due to arcing can be prevented. A contamination of the material layer due to particles created by the arcing and/or parasitic plasmas can be reduced or even avoided. A homogeneity and purity of the material layer deposited on the substrate can be improved.

Further, the one or more conductive sheets are detachably mounted on the frame assembly. The shielding device allows for a facilitated maintenance and a reduced downtime of the system, for example, an in-line processing system. An efficiency and throughput of the system can be increased. In some implementations, the one or more conductive sheets can be reusable or disposable. In particular, chemical cleaning and/or sandblasting can be employed to remove the deposition material from the reusable conductive sheets. In other implementations, the one or more conductive sheets can be disposable and can be replaced, for example, when the one or more conductive sheets are damaged and/or excessively covered with deposition material. The disposable conductive sheets can be made thin, since no cleaning process, such as sandblasting, is performed that would damage or deform the conductive sheets.

The term “arcing” as used herein refers to an electric flashover between two points having different electric potentials. As an example, “arcing” can be understood as an electric current that flows across an open space or along a material surface, such as a dielectric material surface, between two points having different electrical potentials, i.e., there is a potential difference between the two points. When the potential difference exceeds a threshold value, arcing can occur. The threshold value can be referred to as “flash-over voltage” or “sparkover” voltage. The two points of different electrical potentials could be provided by the sputter deposition source (e.g., a target) and, for example, a portion of the carrier or another point provided within the sputter deposition chamber in which the carrier, the substrate and the sputter deposition source are located. The marks or arcing events across a material surface can also be referred to as “crazing”.

The shielding device of the present disclosure has a flat electrically conductive surface which provides an equipotential surface in the AC environment to reduce arcing and crazing. Further, the shielding device covers dead volumes at the chamber wall substantially RF-tight to reduce or even prevent the occurrence of parasitic plasma.

The system, the shielding device, and the method of the present disclosure can be configured for use in a sputter deposition process using a power supply providing an AC signal or AC signal portion and/or a DC signal or DC signal portion. An example, the sputter deposition process can be an AC sputter deposition process. The AC sputter deposition process is a sputter deposition process where the sign of the cathode voltage is varied at a predetermined rate, for example, 2 MHz, 13.56 MHz, particularly 27.12 MHz, more particularly 40.68 MHz, a multiple of 13.56 MHz, or any combination thereof. According to some embodiments, which can be combined with other embodiments described herein, the sputter deposition process can utilize an AC power supply such as a HF (high frequency) or a RF (radio frequency) power supply, a DC power supply, a combination of a DC and AC power supply, a mixed AC power supply, in which AC signals or pulses having different frequencies and/or amplitudes are provided, a pulsed DC power supply, a combination of a pulsed DC and AC power supply, a combination of a DC and mixed AC power supply, or a combination of a pulsed DC and mixed AC power supply.

In some implementations, the substrate is an inflexible substrate, e.g., a plate, or a flexible substrate such as a web or a foil. As an example, the substrate can have a thickness of less than 1 mm, specifically less than 0.1 mm, and more specifically less than 50 μm. According to some embodiments, the substrate can be made from any material suitable for material deposition. For instance, the substrate can be made from a material selected from the group consisting of glass (for instance soda-lime glass, borosilicate glass etc.), semiconductor, metal, polymer, ceramic such as a glass ceramic or YSZ (yttria-stabilized zirconia), compound materials, carbon fiber materials, mica or any other material or combination of materials which can be coated by a deposition process. As an example, the substrate can be made of a glass ceramic, such as LAS systems (e.g., Li2O, Al2O3, SiO2 based), MAS systems (MgO, Al2O3, SiO2 based), and ZAS systems (ZnO, Al2O3, SiO2 based).

The embodiments described herein can be utilized for physical deposition such as physical vapor deposition on substrates, e.g., for battery or display manufacturing. Specifically, the substrates can be large area substrates. Large area substrates can have sizes starting from 0.01 m². For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. According to some embodiments, carriers according to the present disclosure can be configured to support one large area substrate or multiple small substrates, for example, having sizes starting from 0.0005 m². Although the substrates or substrate carriers, for which the structures and methods according to embodiments described herein are provided, are large area substrate, the present disclosure is not limited thereto.

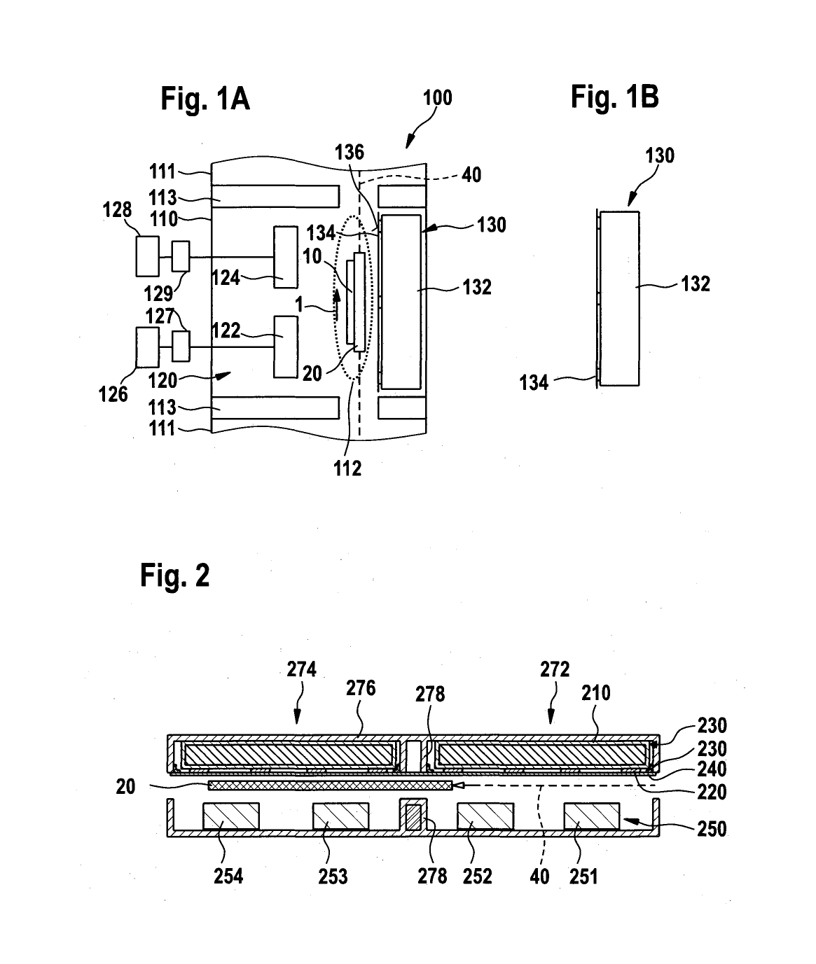

FIG. 1A shows a schematic top view of a system 100 configured for sputter deposition on a substrate according to embodiments described herein. FIG. 1B shows a schematic top view of a shielding device 130 for a sputter deposition chamber according to embodiments described herein.

The system 100 includes a sputter deposition chamber 110 having a processing zone 112, one or more sputter deposition sources 120 arranged at a first side of the processing zone 112, and a shielding device 130 arranged at a second side of the processing zone 112. The shielding device 130 includes a frame assembly 132 mounted to the sputter deposition chamber 110 and one or more conductive sheets 134 detachably mounted on the frame assembly 132. The one or more conductive sheets 134 provide a surface 136, such as a conductive surface, arranged along at least a portion of the processing zone 112. The one or more conductive sheets 134, and specifically the surface 136, are configured to face towards the processing zone 112. As an example, one or more conductive sheets 134 are configured to face towards the one or more sputter deposition sources 120. The system 100 can be an in-line system, for example, an in-line RF sputtering system.

According to some embodiments, the shielding device 130 can have at least two conductive sheets, at least for conductive sheets, and more specifically at least six conductive sheets. The plurality of conductive sheets provide the surface 136. In particular, a surface of each of the conductive sheets can be at least 0.1 m², specifically at least 0.5 m², specifically at least 1 m², specifically at least 2 m², and more specifically at least 3 m². As an example, the surface of each of the conductive sheets can be about 0.5 m². The sum of the surfaces of the individual conductive sheets can correspond to the surface 136. In some implementations, the shielding device 130 can be referred to as “electrical shielding”, “electrical shielding device”. The one or more conductive sheets can be referred to as “shielding plates”.

In some embodiments, the processing zone can be an area or zone where the substrate 10 can be processed. For example, the substrate may be positioned in the processing zone, and material may be deposited thereon to form, e.g., a layer for a thin film transistor. The processing zone 112 can be located to face the one or more sputter deposition sources 120. The processing zone 112 can be an area or region, which is provided and/or arranged for the deposition (the intended deposition) of the deposition material on the substrate 10. The processing zone 112 can be positioned between the one or more sputter deposition sources 120 and the shielding device 130.

In some implementations, the first side and the second side of the processing zone 112 are opposite sides of the processing zone 112. In the example of FIG. 1A, the first side is the left side of the processing zone 112 and the second side is the right side of the processing zone 112. The first side can be (directly) adjacent to the one or more sputter deposition sources 120. The second side can be (directly) adjacent to the shielding device 130, and specifically adjacent to the one or more conductive sheets 134.

The one or more sputter deposition sources 120 can provide respective plasma zones (not shown). During the sputter deposition process, the plasma zones can be directed towards the processing zone 112. The deposition material is provided in the plasma zone. As an example, the magnet assemblies of the sputter cathodes can be utilized to confine the plasma for improved sputtering conditions. In some implementations, the plasma zone can be understood as the sputtering plasma or a sputtering plasma region provided by the sputter deposition source. The plasma confinement can also be utilized for adjusting a participle distribution of the material to be deposited on the substrate 10. In some embodiments, the plasma zone corresponds to a zone that includes the atoms of the target material (the deposition material) that are ejected or released from the target. The plasma zone can be confined by the magnet assemblies, i.e. magnetrons, wherein the ions and electrons of processing gases and/or deposition material are confined in the proximity of the magnetrons or magnet assembly. At least some of the atoms ejected or released from the target are deposited on the substrate to form a material layer.

According to some embodiments, which can be combined with other embodiments described herein, the one or more conductive sheets 134 are arranged along a full extent of the processing zone 112. In other words, the one or more conductive sheets 134 can extend over a full side or length of the processing zone 112. The extent or length of the processing zone 112 can be defined in a direction parallel to a substrate transportation path 40 extending through the processing zone 112. In some implementations, the one or more conductive sheets 134 can extend over at least 50%, specifically at least 70%, specifically at least 90%, and more specifically 100% of the extent or length of the processing zone 112.

According to some embodiments, which can be combined with other embodiments described herein, the surface of the one or more conductive sheets 134 is configured to provide an equipotential surface. In particular, the equipotential surface can be provided by the surface 136, e.g., the conductive surface. The term “equipotential surface” as used throughout the present disclosure refers to a surface of substantially constant scalar potential. In particular, the equipotential surface can be defined with respect to at least one sputter deposition source of the one or more sputter deposition sources 120. The equipotential surface can be substantially perpendicular to the net electric field lines passing through the equipotential surface. It is to be understood that the surface of the one or more conductive sheets 134 can have elevations and/or depressions, for example, due to at least one of manufacturing tolerances, alignment tolerances, and the mounting of the one or more conductive sheets to the frame assembly. Still, the surface of the one or more conductive sheets 134 is to be understood as “equipotential surface” or “flat equipotential surface”.

According to some embodiments, the sheet has a thickness that is considerably smaller than the length and breadth of the sheet. As an example, the one or more conductive sheets 134 have a thickness of less than 10 mm, specifically less than 5 mm, specifically less than 3 mm, specifically less than 2 mm, and more specifically less than 1 mm. As an example, the one or more conductive sheets 134 have a thickness of about 3 mm. The one or more conductive sheets 134 are supported by, and fixed to, the frame assembly 132 and can have a reduced thickness. An amount of material used for the one or more conductive sheets 134 can be reduced. Manufacturing costs can be lowered. Further, the one or more conductive sheets 134 have a reduced weight, facilitating a mounting and demounting (e.g., a replacement) of the one or more conductive sheets 134. In some implementations, the one or more conductive sheets 134 provide a thin, disposable shielding, for example, made of aluminum.

The term “conductive” used in terms like “conductive sheet” and “conductive surface” refers to electrical conductivity. As an example, the conductive sheets and/or the conductive surface can have a conductivity of at least 10⁵ (S/m) at 20° C., specifically at least 10⁶ (S/m) at 20° C., and more specifically at least 10⁷ (S/m) at 20° C. S/m denotes the SI units of the conductivity, namely Siemens per meter.

According to some embodiments, which can be combined with other embodiments described herein, a material of the one or more conductive sheets 134 is selected from the group consisting of aluminum, copper, steel (e.g., stainless steel), titanium, and any combination thereof. However, the present disclosure is not limited thereto, and other electrically conductive materials can be used for the one or more conductive sheets 134.

According to some embodiments, which can be combined with other embodiments described herein, the one or more conductive sheets 134 have a roughened surface. As an example, the roughened surface can have roughness in the range of Rz10 to Rz100, specifically in the range of Rz20 to Rz50, and more specifically in the range of Rz25 to Rz40. In some implementations, the roughened surface can be provided by sandblasting, for example, with glass beads and/or electro corundum. Deposition material that does not reach the substrate can adhere to the roughened surface. A flaking of the deposited material can be reduced or even avoided, even if the one or more conductive sheets 134 are flittering. In particular, a particle generation due to a flake off of material deposited on the one or more conductive sheets 134 can be reduced or even avoided. A purity of the material layer deposited on the substrate 10 can be improved. Further, a particle generation or flaking can be avoided for a longer period, and the one or more conductive sheets 134 can be replaced less frequently. A system uptime can be increased.

In some implementations, the one or more conductive sheets 134 are coated with a rough surface coating or adhesive coating for better adhesion. As an example, the surface 136 of the one or more conductive sheets 134 facing towards the processing zone 112 or the substrate transportation path 40 can be coated. According to some embodiments, the one or more conductive sheets 134, for example, the surface 136 facing towards the processing zone 112 or substrate transportation path 40, can be coated with at least one of a dielectric coating and the rough surface coating to avoid arcing. For example, the dielectric coating can be selected from the group consisting of Al₂O₃, SiO₂, and YSZ (yttria-stabilized zirconia). A surface of the coating can provide the equipotential surface.

Referring to FIG. 1A, the system 100 has one or more substrate transportation paths 40 extending through the sputter deposition chamber 110. Specifically, the one or more substrate transportation paths 40 can extend through the processing zone 112. The substrate transportation path 40 is configured for transportation of the substrate 10 or a substrate carrier 20 having the substrate 10 positioned thereon through the sputter deposition chamber 110, and specifically through the processing zone 112. The one or more substrate transportation paths 40 can be provided between the shielding device 130 and the one or more sputter deposition sources 120.

The one or more conductive sheets 134 can be configured to face towards the substrate transportation path 40. In particular, the surface 136 of the one or more conductive sheets 134 can be provided opposite the substrate transportation path 40. The one or more conductive sheets 134 can be aligned with respect to the substrate transportation path 40 and/or the one or more sputter deposition sources 120. As an example, the surface 136 of the one or more conductive sheets 134 can be substantially parallel to the substrate transportation path 40.

According to some embodiments, the transportation path is a way along which the substrate carrier 20 can be moved or conveyed in the sputter deposition chamber 110. As an example, the substrate transportation path 40 can be a linear transportation path. The substrate transportation path 40 can define a transport direction 1 for the substrate carrier 20 through the sputter deposition chamber 110. The substrate transportation path 40 can be a unidirectional transportation path or can be a bidirectional transportation path. In some implementations, two or more substrate transportation paths can be provided. As an example, the two or more substrate transportation paths can extend substantially parallel to each other through the sputter deposition chamber 110.

The substrate carrier 20 is configured to support the substrate 10, for example, during a sputter deposition process, such as an RF sputtering process. The substrate carrier 20 can include a plate or a frame configured for supporting the substrate 10, for example, using a support surface provided by the plate or frame. Optionally, the substrate carrier 20 can include one or more holding devices (not shown) configured for holding the substrate 10 at the plate or frame. The one or more holding devices can include at least one of mechanical and/or magnetic clamps. In some implementations, the carrier is an electrostatic chuck.

According to some embodiments described herein, the system 100 includes the sputter deposition chamber 110 (also referred to as “deposition chamber” or “vacuum processing chamber”) and the one or more sputter deposition sources 120, such as a first sputter deposition source 122 and a second sputter deposition source 124, in the sputter deposition chamber 110. The one or more sputter deposition sources 120 such as the first sputter deposition source 122 and the second sputter deposition source 124 can, for example, include planar cathodes having targets of the material to be deposited on the substrate. However, the present disclosure is not limited to planar cathodes or targets. Other cathodes, such as rotatable cathodes, can be similarly implemented.

According to some embodiments, which can be combined with other embodiments described herein, the frame assembly 132 of the shielding device 130 is mounted to a chamber wall, such as a vertical chamber wall, of the sputter deposition chamber 110. As an example, the frame assembly 132 can be mounted on a chamber body or a back wall of the sputter deposition chamber 110.

In some implementations, the shielding device 130, and specifically the one or more conductive sheets 134, are aligned with respect to at least one of the processing zone 112, the substrate transportation path 40 and the one or more sputter deposition sources 120. As an example, the shielding device 130, and specifically the one or more conductive sheets 134, are aligned or positioned such that the one or more conductive sheets 134 provide the equipotential surface with respect to the one or more sputter deposition sources 120, for example, a surface of the planar cathode(s) or planar target(s). In particular, the shielding can be aligned along one geometrical line with an in-line RF sputter deposition system, for example, the planar targets, to provide for the flat equipotential surface or area.

In some embodiments, the surface 136 of the one or more conductive sheets 134 facing towards the substrate transportation path 40 or processing zone 112 and a surface of the planar target facing towards the substrate transportation path 40 or processing zone 112 can be substantially parallel. The term “substantially parallel” relates to a substantially parallel orientation e.g. of the surface of the one or more conductive sheets 134 and the surface of the planar target(s), wherein a deviation of a few degrees, e.g. up to 10° or even up to 15°, from an exact parallel orientation is still considered as “substantially parallel”.

As indicated in FIG. 1A, further chambers 111 can be provided adjacent to the sputter deposition chamber 110. The sputter deposition chamber 110 can be separated from adjacent chambers by valves 113 having, for example, a valve housing and a valve unit. After the substrate carrier 20 with the substrate 10 thereon is inserted into the sputter deposition chamber 110, the valve 113 can be closed. In some implementations, no valves are provided between adjacent chambers. The atmosphere in the sputter deposition chamber 110 can be individually controlled by generating a technical vacuum, for example with vacuum pumps connected to the sputter deposition chamber 110, and/or by inserting process gases in a deposition region in the sputter deposition chamber 110.

According to some embodiments, process gases can include inert gases such as argon and/or reactive gases such as oxygen, nitrogen, hydrogen and ammonia (NH3), Ozone (O3), activated gases or the like. Within the sputter deposition chamber 110, a transport system including at least one of rollers and magnetic devices can be provided in order to transport the substrate carrier 20 along the substrate transportation path 40 into, through, and out of the sputter deposition chamber 110.

The sputter deposition process can use at least one of AC power, DC power, or a combination thereof. As an example, the sputter deposition process can be an AC sputter deposition process. The AC sputter deposition process can be a sputter deposition process where the sign of the cathode voltage is varied at a predetermined rate, for example, 2 MHz, 13.56 MHz, particularly 27.12 MHz, more particularly 40.68 MHz, a multiple of 13.56 MHz, or any combination thereof. According to some embodiments, which can be combined with other embodiments described herein, the AC sputter deposition process can be a HF (high frequency) or RF (radio frequency) sputter deposition process. However, the present disclosure is not limited to sputter deposition processes using AC power and the embodiments described herein can be used in other sputter deposition processes, such as DC sputter deposition processes.

According to some embodiments described herein, the system 100 can have one or more power supplies connected to the one or more sputter deposition sources 120. In some implementations, each sputter deposition source can have its own power supply. As an example, a first power supply 126 of the one or more power supplies can be connected to the first sputter deposition source 122, for example, via a first matchbox 127. A second power supply 128 of the one or more power supplies can be connected to the second sputter deposition source 124, for example, via a second matchbox 129. In other implementations, the one or more sputter deposition sources 120 can be connected to the same power supply, for example, via one or more matchboxes.

In some implementations, the power supply feed-in is connected via a matchbox to the target, whereas a gas shower surrounding the target is electrically connected with the chamber body (RF-grounded) and is used as RF return path to the respective matchbox and respective power supply. The electrical shielding on the opposing side is also DC and RF grounded to the chamber body and provides for a defined RF return path to the front.

According to some embodiments, the one or more power supplies can be configured for at least one of AC power supply, DC power supply, pulsed DC power supply, AC/DC power supply and mixed signal power supply. The AC power supplies are configured for generation of AC (sinusoidal or pulsed) power or power signals. The AC/DC power supplies are configured for generation of a combination of AC and DC power or power signals. The mixed signal power supplies are configured for generation of power or power signals having AC signals or pulses having different frequencies or amplitudes. As an example, the power supplies can be selected from the group consisting of AC power supplies, DC power supplies, combinations of DC and AC power supplies, mixed AC power supplies, pulsed DC power supplies, combinations of pulsed DC and AC power supplies, combinations of DC and mixed AC power supplies, combinations of pulsed DC and mixed AC power supplies, and any combination thereof.

According to some embodiments described herein, the sputter deposition process can be conducted as magnetron sputtering. As used herein, “magnetron sputtering” refers to sputtering performed using a magnet assembly, e.g., a unit capable of generating a magnetic field. Such a magnet assembly can consist of a permanent magnet. This permanent magnet can be arranged coupled to a planar target in a manner such that the free electrons are trapped within the generated magnetic field generated below the target surface.

According to some embodiments, which can be combined with other embodiments described herein, the system 100 can be configured to deposit an insulating material on the substrate 10. As an example, the system 100 can use an insulating target material for deposition on the substrate 10. The system 100 can be used for deposition of at least one material selected from the group consisting of semiconductors (e.g., InGaZnO), transparent conductive oxides (transparent conductive oxides (TCOs), e.g. ITO, AZO, IZO), battery electrolytes such as LiPON, and battery cathode materials (e.g. LiCoO, LiCoAlO, LiGaCoO, LiNiCoO, LiMnO, LiMgCoO, LiFePO, LiMFePO4 (M=Zr, Nb, Mg, Co, Mn, Ni or a combination thereof) LiBMnO, and vanadium oxide).

The system, shielding device and method described herein can be used for vertical substrate processing. According to some implementations, the carrier 20 of the present disclosure is configured to hold the substrate 10 in a substantially vertical orientation. The term “vertical substrate processing” is understood to distinguish over “horizontal substrate processing”. For instance, vertical substrate processing relates to a substantially vertical orientation of the carrier 20 and the substrate 10 during substrate processing, wherein a deviation of a few degrees, e.g. up to 10° or even up to 15°, from an exact vertical orientation is still considered as vertical substrate processing. The vertical direction can be substantially parallel to the force of gravity. As an example, the system 100 configured for sputter deposition on a substrate 10 can be configured for sputter deposition on a vertically oriented substrate.

According to some embodiments, which can be combined with other embodiments described herein, the carrier 20 and the substrate 10 are static or dynamic during sputtering of the deposition material. According to some embodiments described herein, a dynamic sputter deposition process can be provided, e.g., for battery or display manufacturing. The embodiments of the present disclosure can be particularly beneficial for such dynamic sputter deposition processes, since electrically conducting materials moving through a RF plasma can cause arcing due to different electrical potentials. The shielding device provided by the embodiments of the present disclosure can reduce or even avoid the occurrence of arcing in such a dynamic system. Moreover, the shielding device helps to keep the RF plasma conditions homogenous, what is beneficial for film deposition with uniform film properties.

FIG. 2 shows a schematic top view of a system configured for sputter deposition on a substrate (not shown) according to further embodiments described herein.

According to some embodiments, which can be combined with other embodiments described herein, the system has two or more sputter deposition chambers, such as a first sputter deposition chamber 272 and a second sputter deposition chamber 274. The two or more sputter deposition chambers can be separated using valves 278, similar to the valve described with reference to FIG. 1A.

Each sputter deposition chamber of the two or more sputter deposition chambers can have one or more sputter deposition sources 250. As an example, the first sputter deposition chamber 272 can have a first sputter deposition source 251 and a second sputter deposition source 252. The second sputter deposition chamber 274 can have a third sputter deposition source 253 and a fourth sputter deposition source 254. The substrate transportation path 40 can extend at least through the two or more sputter deposition chambers. In some implementations, the substrate can be transported through the two or more sputter deposition chambers for deposition of two or more material layers on the substrate.

According to some embodiments, each sputter deposition chamber includes a shielding device. As an example, the first sputter deposition chamber 272 can include a first shielding device and the second sputter deposition chamber 274 can include a second shielding device. The shielding device can be mounted to a chamber wall, such as a back wall 276, of the sputter deposition chamber. The shielding devices of two adjacent sputter deposition chambers, and specifically the one or more conductive sheets 240 of the respective shielding devices, can be configured to join together substantially seamlessly. In particular, the shielding devices, and specifically the one or more conductive sheets 240 of the shielding devices, can be aligned with respect to each other so as to provide a substantially continuous equipotential surface extending through the two or more sputter deposition chambers. In particular, the substantially continuous equipotential surface can also be provided in a connection region of adjacent sputter deposition chambers, such as in a region of the valve 278.

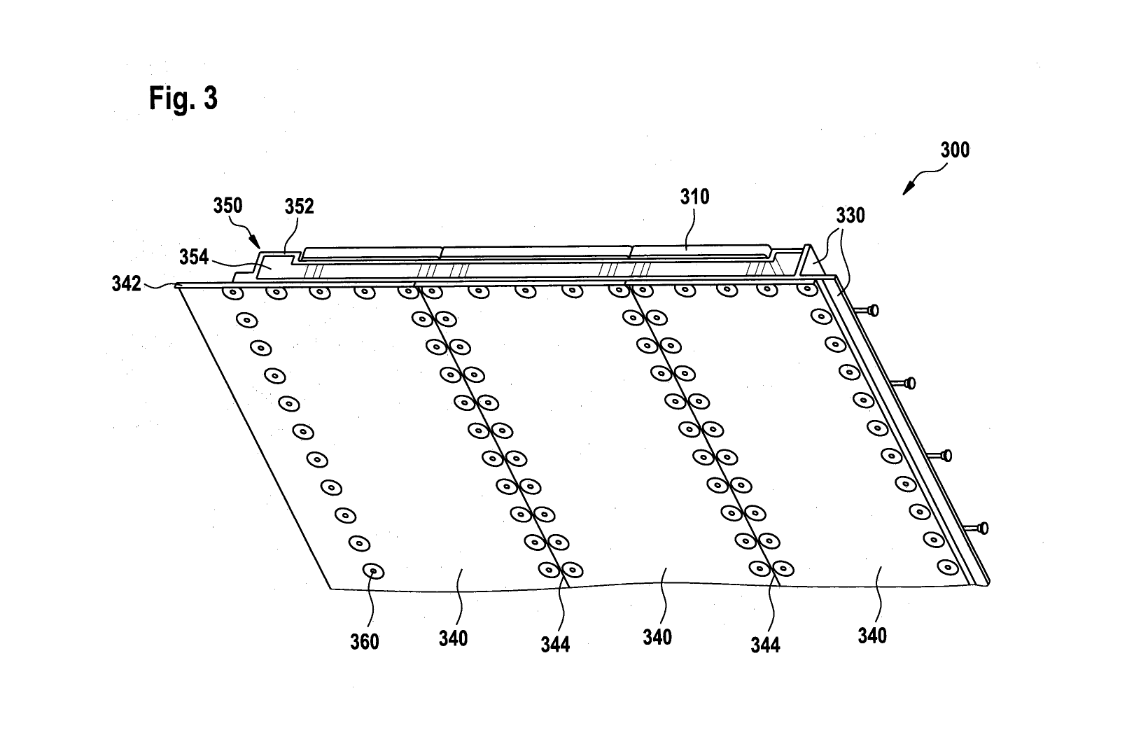

According to some embodiments, which can be combined with other embodiments described herein, the frame assembly includes a base frame 210, a mounting frame 220 and one or more side frame elements 230. The one or more conductive sheets 240 can be mounted to the mounting frame 220. The frame assembly can allow for a correct positioning of the shielding device in the sputter deposition chamber. The frame assembly having the triple frame structure can allow for a facilitated maintenance of the shielding device, for example, a replacement of the one or more conductive sheets 240. The frame assembly of the shielding device is further explained with reference to FIGS. 3 to 6.

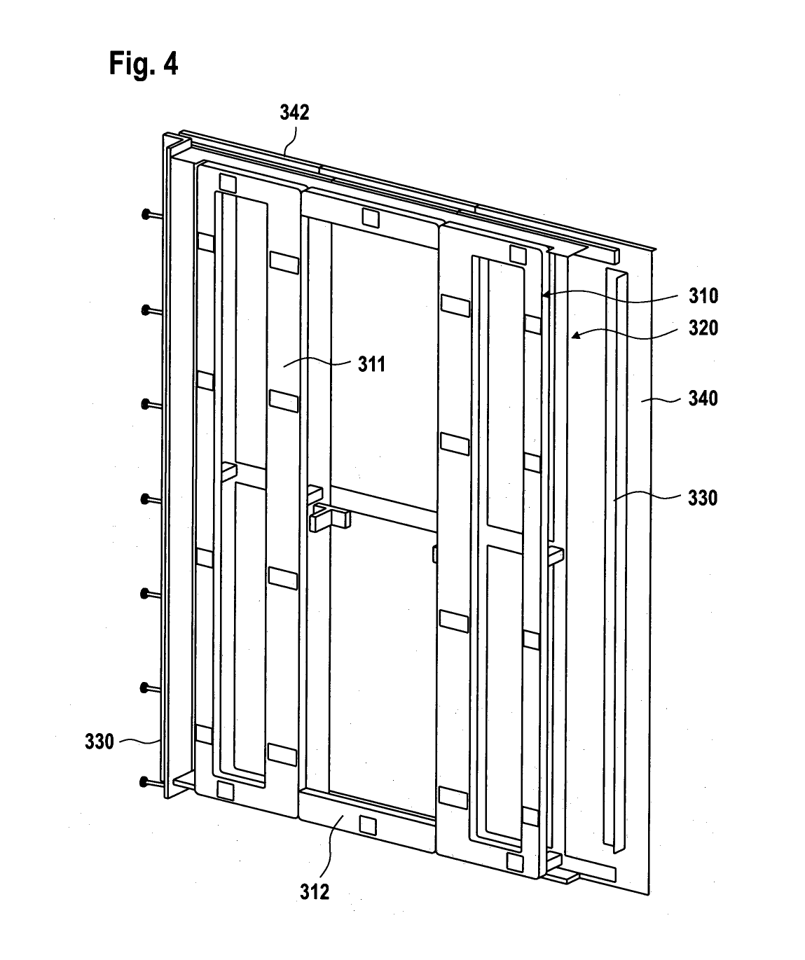

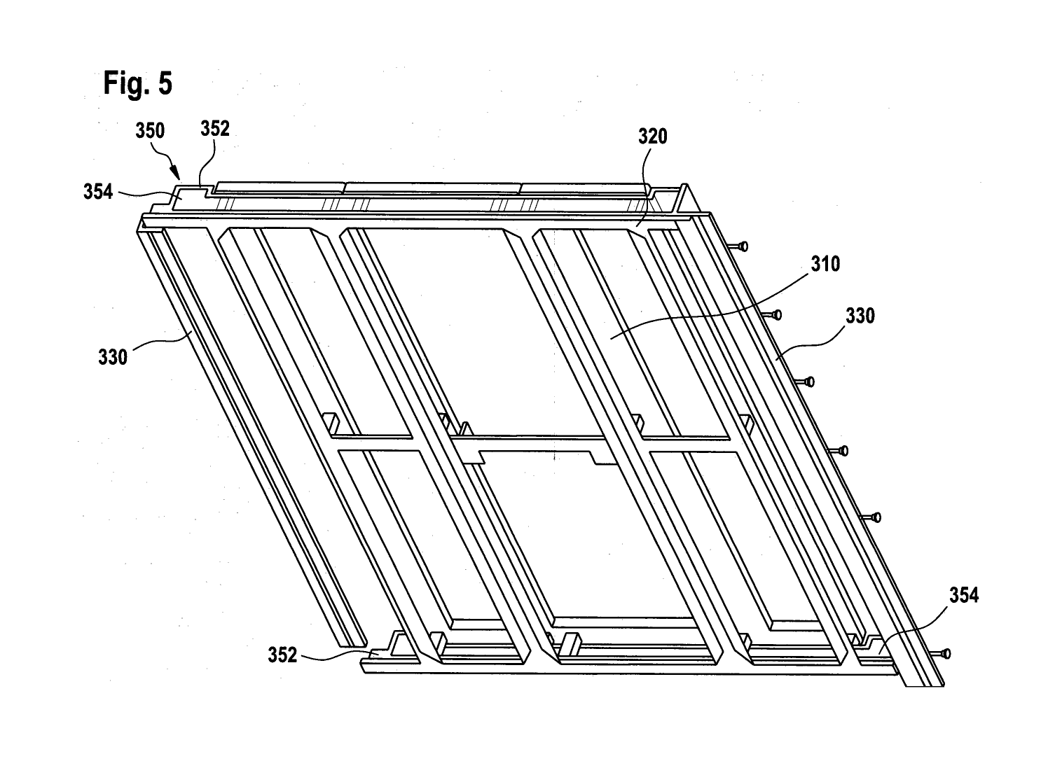

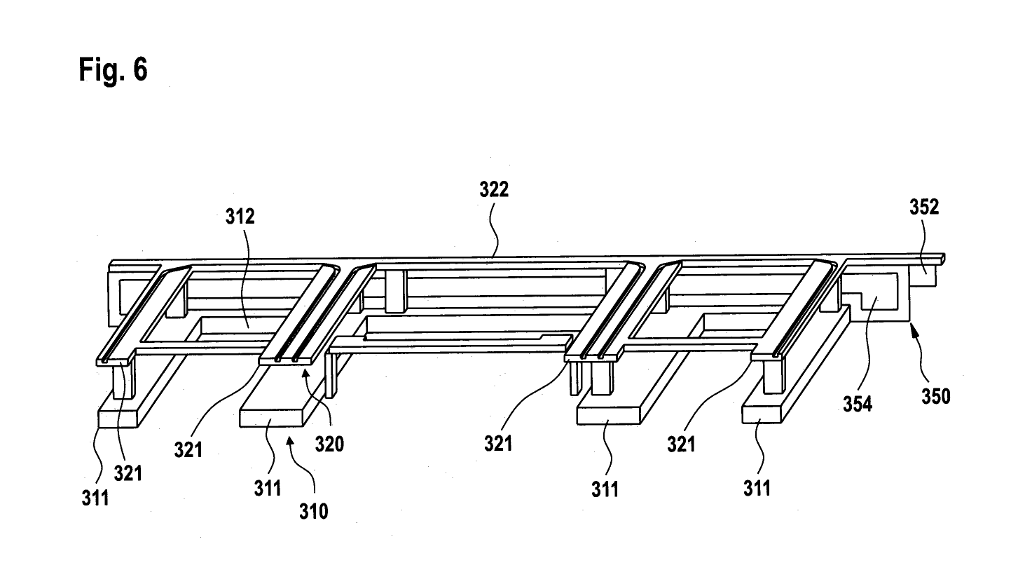

FIG. 3 shows a perspective front view of a shielding device 300 for a sputter deposition chamber according to embodiments described herein. FIG. 4 shows a perspective rear view of the shielding device 300 of FIG. 3. FIG. 5 shows a schematic view of the frame assembly of the shielding device 300 according to embodiments described herein. FIG. 6 shows a cross-sectional schematic view of the frame assembly of FIG. 5.

According to some embodiments, which can be combined with other embodiments described herein, the frame assembly includes a base frame 310 connectable to the sputter deposition chamber. In particular, the base frame 310 can be connectable to the chamber wall, such as the back wall of the sputter deposition chamber. According to some embodiments, the base frame 310 can be detachably connected to the sputter deposition chamber, for example, using at least one of screws and clamps. In other implementations, the base frame 310 can be welded to the sputter deposition chamber, for example, the back wall of the sputter deposition chamber.

In some implementations, the base frame 310 has one or more longitudinal base bars 311, for example, one or more vertical base bars. The base frame 310 can have one or more cross base bars 312, for example, one or more horizontal base bars. The base frame 310 can be made of a material selected from the group consisting of SuS (“Steel Use Stainless”: Japanese steel grades) material, Al, and AlMg₃.

According to some embodiments, which can be combined with other embodiments described herein, the frame assembly includes a mounting frame 320 having a mounting surface. The one or more conductive sheets 340 can be detachably mounted on the mounting surface. As an example, the mounting frame 320 can be configured to support the one or more conductive sheets 340. The one or more conductive sheets 340 can be fixedly mounted to the mounting frame 320 so as to reduce or even avoid movements, such as flittering, of the one or more conductive sheets 340. In some implementations, the mounting frame 320 can be referred to as “connector frame”.

According to some embodiments, the mounting frame 320 can provide a connection or interface between the one or more conductive sheets 340 and the base frame 310. In some embodiments, the mounting frame 320 can be configured to be detachably mounted to the base frame 310, for example, using at least one of screws and clamps. In other implementations, the mounting frame 320 can be welded to the base frame 310.

In some implementations, the mounting frame 320 has one or more longitudinal mounting bars 321, for example, one or more vertical mounting bars. The mounting frame 320 can have one or more cross mounting bars 322, for example, one or more horizontal mounting bars. The mounting frame 320 can be made of aluminum.

The term “horizontal” is understood to distinguish over “vertical”. That is, “horizontal” and “vertical” relate to a substantially horizontal or vertical orientation e.g. of the frame assembly or the bars of the base frame 310 and/or the mounting frame 320, wherein a deviation of a few degrees, e.g. up to 10° or even up to 15°, from an exact horizontal or vertical orientation is still considered as “horizontal” or “vertical”. The vertical direction can be substantially parallel to the force of gravity.

According to some embodiments, which can be combined with other embodiments described herein, the frame assembly includes one or more side frame elements 330. The one or more side frame elements 330 can provide a lateral termination of the shielding device 300, and specifically of the one or more conductive sheets 340. The one or more side frame elements 330 can seal a space between the shielding device 300, for example, between at least one of the base frame 310 and the mounting frame 320, and one or more walls of the sputter deposition chamber. Volumes (e.g., dead volumes) behind the shielding device 300 can be sealed or covered against RF penetration. RF wave penetration in such volumes can be prevented, reducing or even avoiding the occurrence of parasitic plasmas. In particular, RF leaking behind the (wall) shielding and the occurrence of parasitic plasma can be avoided. In some implementations, the one or more side frame elements 330 can be referred to as “side connector frame”.

In some implementations, the one or more side frame elements 330 can be bars, for example, L-shaped bars. For instance, the one or more side frame elements 330 can have a mounting surface, wherein at least a portion of the one or more conductive sheets 340 are detachably mounted on the mounting surface of the one or more side frame elements 330. The mounting surface of the one or more side frame elements 330 can be substantially parallel to the mounting surface of the mounting frame 320 in a state where the frame assembly is assembled. The one or more side frame elements can be made of aluminum.

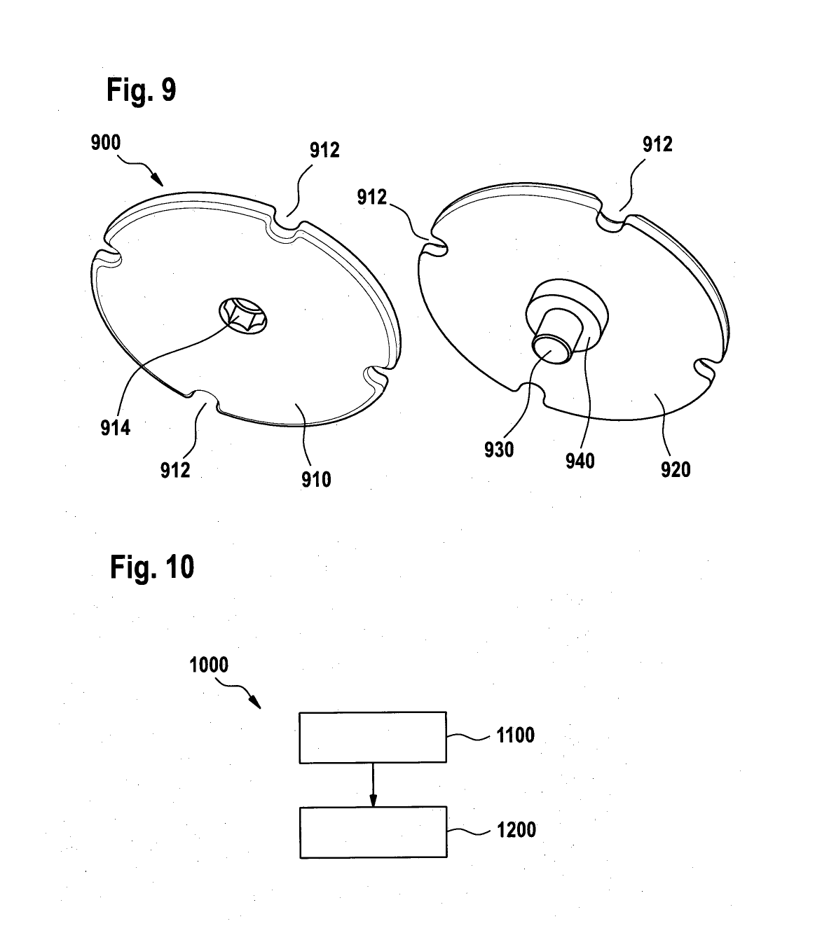

According to some embodiments, which can be combined with other embodiments described herein, the shielding device 300 includes one or more mounting devices 360 configured to mount the one or more conductive sheets 340 to the frame assembly. As an example, the one or more mounting device 360 are screws. The mounting device is further explained with reference to FIG. 9.

In some implementations, the one or more conductive sheets 340 can have a fold or beading 342, for example, at least one of a top side and bottom side of the one or more conductive sheets 340. In particular, the one or more conductive sheets can have a top side, a bottom side and lateral sides. The top side can be defined as the upper side of the one or more conductive sheets 340 when the one or more conductive sheets 340 are in an upright position, for example, vertically oriented. The fold or beading 342 can stabilize the one or more conductive sheets 340, for example, against horizontal bending.

According to some embodiments, which can be combined with other embodiments described herein, the frame assembly includes a conductive mesh 354 or grid provided at at least one of a top (e.g., the top side) and a bottom (e.g., the bottom side) of the frame assembly. The conductive mesh 354 can be a metal mesh. As an example, the material of the metal mesh can be selected from the group consisting of metal, Cu, and steel such as stainless steel. In some implementations, the frame assembly includes a mesh assembly 350 including a mesh frame 352 and the conductive mesh 354. The mesh frame 352 can have an aperture opening, wherein the conductive mesh 354 can be provided in the aperture opening. The mesh frame 352 can be configured to be mounted on the top side and/or the bottom side of the frame assembly. For example, the mesh frame 352 can be configured to be mounted to the base frame 310.

The mesh assembly 350 can cover a space between the shielding device 300 (e.g., at least one of the one or more conductive sheets 340) and one or more walls of the sputter deposition chamber, for example, the back wall. The conductive mesh 354 can reduce or even prevent an RF leaking behind the shielding (the one or more conductive sheets) to avoid parasitic plasma generation in volumes behind the shielding. The conductive mesh 354 can also be referred to as “RF mesh”. In some implementations, the conductive mesh 354 can have openings, wherein a size (e.g., a diameter) of the openings can be configured to prevent RF waves from passing through the conductive mesh 354. According to some embodiments, the sizes of the openings can be smaller than the wavelength(s) of the RF waves. For example, the sizes of the openings are smaller than the wavelength(s) of the RF waves.

The openings in the conductive mesh 354 allow for a vacuum pumping of the backside volume, for example, the volume behind the one or more conductive sheets 340. The volume behind the one or more conductive sheets 340 can include, or be, a volume between the back wall of the sputter deposition chamber and the shielding device 300. Vacuum conditions can be established in the sputter deposition chamber even after the shielding device 300 has been installed, for example, in front of the back wall.

According to some embodiments, which can be combined with other embodiments described herein, a gap 344 is provided between two adjacent conductive sheets. The gap 344 can extend substantially vertically between the two adjacent conductive sheets. The gap 344 allows for thermal expansion of the conductive sheets 340 in the horizontal direction.

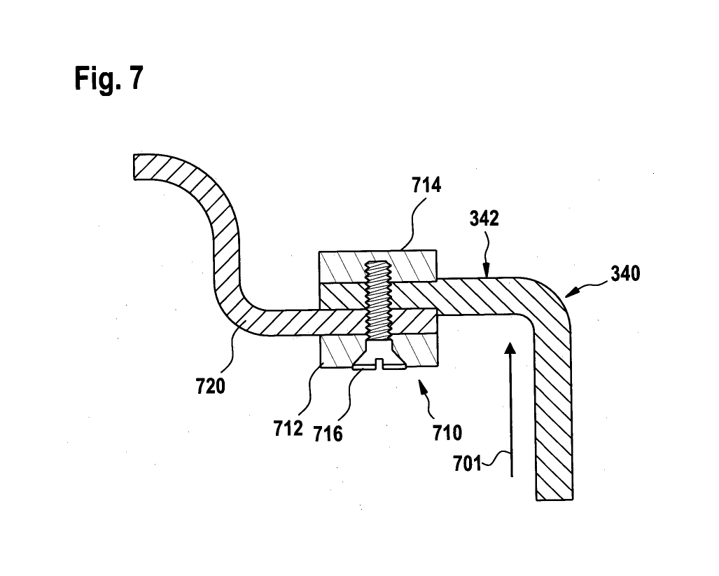

FIG. 7 shows a schematic view of a grounding device attached to the shielding device according to embodiments described herein.

According to some embodiments, which can be combined with other embodiments described herein, the shielding device includes one or more grounding devices configured to ground at least one of the frame assembly and the one or more conductive sheets 340. In some implementations, the one or more grounding devices can be configured to provide at least one of DC (direct current) grounding and RF grounding. As an example, the one or more grounding devices can provide an RF return path. Specifically, an RF current on the shielding device can be returned, for example, to a matchbox with minimum RF losses. A direction of the RF-current on a surface of the conductive sheet is indicated with reference numeral 701. An inside of the sputter deposition chamber, for example, an internal front of the chamber body is a well-defined surface with respect to an RF return-path/RF grounding as its surface is connected without interruption via the RF grounding device to the surface adjacent to the sputter target. This adjacent surface, e.g., the gas shower, is serving as a receiving area for RF return as it is connected to the matchbox and power supply RF ground/return path.

In some implementations, the grounding device includes a connection device 710 and a connection line 720. The connection device 710 can be configured to connect or attach the connection line 720 to the shielding device, for example, at the top side of the shielding device. One connection device 710 can be provided to connect two or more connection lines 720 to the shielding device. In other implementations, each connection line 720 can be connected to the shielding device using a respective connection device.

According to some embodiments, the connection device 710 can be connectable to at least one of the conductive sheet 340, the beading 342 of the conductive sheet 340, the base frame, the connector frame, and the side frame element. The connection device 710 can be a clamp or cleat, such as a copper clamp or copper cleat. The cleat can have a first element 712 and a second element 714. A portion of the connection line 720 and a portion of the shielding device, for example, a portion of the beading 342, can be sandwiched between the first element 712 and the second element 714. One or more screws 716 can be used to connect the first element 712 and the second element 714 to each other so as to mechanically clamp the portion of the connection line 720 and the portion of the shielding device between the first element 712 and the second element 714. The connection device 710, such as the copper cleat, can have rounded edges to facilitate RF current around it and to avoid RF antennas.

The connection line 720 can be a flexible connection line. As an example, the connection line 720 can be a copper band, such as a flexible copper band. The connection line 720 can be connected to the sputter deposition chamber, for example, a wall such as the back wall of the sputter deposition chamber. In particular, the connection line 720 can be connected to a front side of the main chamber body (e.g., an internal chamber body front).

The shielding device can include a plurality of grounding devices periodically arranged at the shielding device, such as the top side (e.g., the horizontal upper side) of the one or more conductive sheets 340. As an example, a plurality of connection devices 710 can be arranged at predetermined distances from each other at the shielding device. According to some embodiments, the predetermined distance can be in a range of 5 cm to 50 cm, specifically in a range of 5 cm to 30 cm, and more specifically in a range of 10 cm to 20 cm. For instance, the predetermined distance can be about 10 cm.

The connection devices 710 and the connection lines 720 can be aligned on the RF-current receiving side of the one or more conductive sheets 340 to provide for an improved RF-contact to avoid RF reflection, for example, from delaminating band edges.

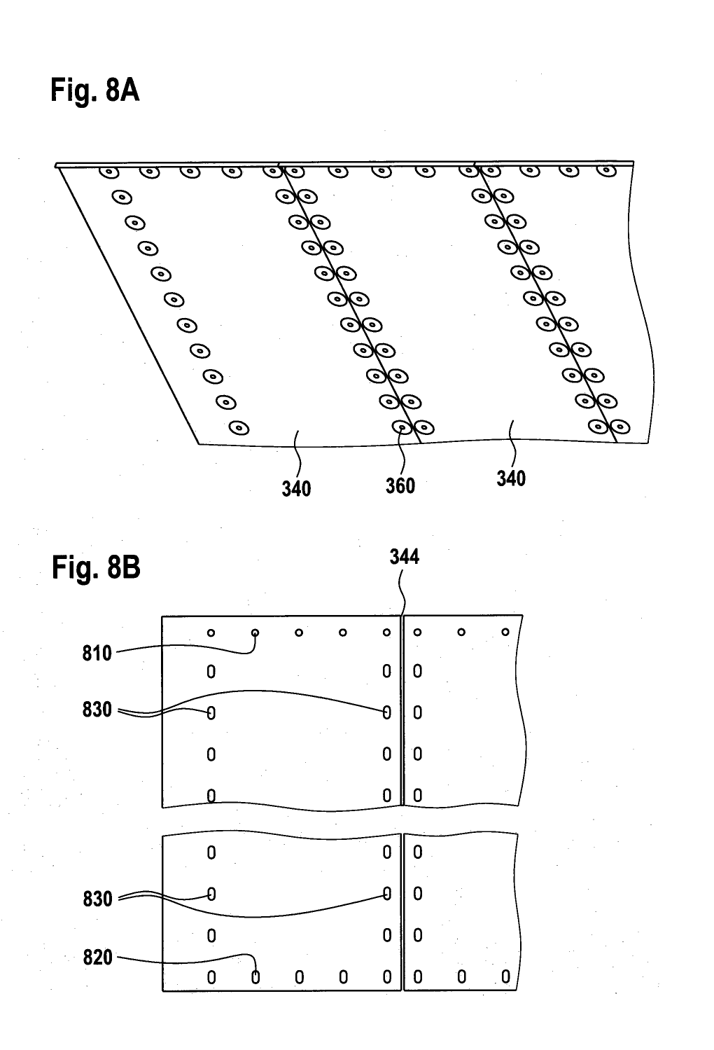

FIGS. 8A and 8B show schematic views of a mounting structure of the shielding device according to embodiments described herein.

According to some embodiments, which can be combined with other embodiments described herein, the shielding device 300 includes one or more mounting devices 360 configured to mount the one or more conductive sheets 340 to the frame assembly. As an example, the one or more mounting device 360 include at least one of screws and Allen keys.

The one or more conductive sheets 340 can have a plurality of through holes. At least some of the plurality of through holes can correspond to respective holes, such as threaded holes, in the connector frame. The mounting devices 360 can be configured to pass through the through holes in the conductive sheets 340 to be inserted into the holes in the connector frame.

In some implementations, the through holes are arranged at periphery portions of the conductive sheet. The through holes can be arranged at at least one of an upper periphery portion (e.g., the top side), a lower periphery portion (e.g., the bottom side), and the lateral periphery portions (e.g., a left side and a right side) of the conductive sheet. As shown in the example of FIG. 8A, the through holes can be arranged at the upper periphery portion (e.g., the top side) and the lateral periphery portions (e.g., a left side and a right side) of the conductive sheet.

The through holes can be arranged along respective lines. As an example, the through holes in the upper periphery portion (e.g., the top side) and/or the through holes in the lower periphery portion (e.g., the bottom side) can be arranged along a substantially horizontal line. The through holes in the lateral periphery portions (e.g., a left side and a right side) can be arranged along a substantially vertical line.

According to some embodiments, at least some of the through holes can be slots or elongated holes (long holes). The slots or elongated holes can be through holes having a length and a width, wherein the length is greater than the width. As an example, the slots or elongated holes can have a substantially rectangular shape with rounded edges. The slots or elongated holes allow for a thermal expansion of the conductive sheet particularly along the longer dimension (length) of the slot or elongated hole. As an example, a pattern of through holes can be provided to accommodate for horizontal and/or vertical thermal expansion of the conductive sheet. In particular, the slots or elongated holes can be oriented so as to allow for a thermal expansion, such as the horizontal and/or vertical thermal expansion, of the conductive sheet. A bending of the conductive sheet can be reduced or even avoided.

In some implementations, the through holes arranged along the horizontal line, for example, in the upper periphery portion (e.g., the top side) and/or the lower periphery portion (e.g., the bottom side) can be longer in the horizontal direction than in the vertical direction. Through holes arranged along the vertical line, for example, in the lateral periphery portions (e.g., a left side and a right side) can be longer in the vertical direction than in the horizontal direction.

According to some embodiments, which can be combined with other embodiments described herein, the through holes include first through holes 810 arranged along the horizontal line in the upper periphery portion (e.g., the top side), second through holes 820 arranged along the horizontal line in the lower periphery portion (e.g., the bottom side) and/or third through holes 830 arranged along the vertical line, for example, in the lateral periphery portions (e.g., a left side and a right side).

The first through holes 810 arranged along the horizontal line in the upper periphery portion (e.g., the top side) can be longer in the horizontal direction than in the vertical direction. Second through holes 820 arranged along the horizontal line in the lower periphery portion (e.g., the bottom side) and/or third through holes 830 arranged along the vertical line, for example, in the lateral periphery portions (e.g., a left side and a right side) can be longer in the vertical direction than in the horizontal direction.

As an example, the second through holes 820 arranged along the horizontal line in the lower periphery portion (e.g., the bottom side) and the third through holes 830 arranged along the vertical line, for example, in the lateral periphery portions (e.g., a left side and a right side) can be substantially identical. In some implementations, the width (smaller dimension) of the through holes arranged along the horizontal line in the lower periphery portion and the through holes arranged along the vertical lines is bigger than the width of the through holes arranged along the horizontal line in the upper periphery portion.

According to further embodiments, at least one of the first through holes 810, the second through holes 820 and the third through holes 830 can be substantially circular through holes. As an example, the first through holes 810 arranged along the horizontal line in the upper periphery portion can be substantially circular through holes.

FIG. 9 shows schematic views of a mounting device 900 configured to mount the one or more conductive sheets to the frame assembly according to embodiments described herein.

According to some embodiments, which can be combined with other embodiments described herein, the mounting device 900 can be plate-shaped or disc-shaped. The mounting device 900 can have a first side or first surface 910 and a second side or second surface 920. The first side (“sputter side”) can be configured to face the processing zone or substrate transportation path, and specifically the one or more sputter deposition sources. The second side (“shielding side”) can be configured to face the conductive sheet. The second side or second surface 920 can have a surface area sufficient to cover the through holes in the conductive sheet. As an example, the surface area can be sufficient to cover the through holes under process conditions when the thermal expansion of the one or more conductive sheets shifts the center position of the through holes. A diameter of the plate or disc can allow for a sufficient coverage of the through holes to avoid RF leakage behind the shielding.

In some implementations, the mounting device 900 has two or more indentations or nudges 912, for example, at the periphery or outside of the plate or disc. The two or more indentations or nudges 912 can be configured for engagement with a tool, for example, for mounting and/or demounting of the mounting device 900. As an example, the mounting device 900 can have four indentations or nudges. The two or more indentations or nudges 912 allow for an easy opening using the tool such as a wrench, despite material deposited on the second side (e.g., the top of the screw head). Additionally or optionally, the mounting device 900 has a centric key, such as a centric Allen key 914, at the first side or first surface 910. The centric key allows for an easy and fast assembling of the mounting device 900.

According to some embodiments, the mounting device 900 has a thread or screw 930, for example, configured for engagement with the threaded holes in the mounting frame. The thread or screw 930 can be provided at the second side or second surface 920, for example, at a center of the second side or second surface 920. In some implementations, the mounting device 900 has a contact protrusion 940 configured to contact the conductive sheet. The contact protrusion 940 can be provided at the second side or second surface 920, for example, at a center of the second side or second surface 920. As an example, the thread or screw 930 can be positioned on the contact protrusion 940. A surface area of the contact protrusion 940 that is configured to contact the conductive sheet can be smaller than a surface area of the second side or second surface 920. Specifically, the surface area of the contact protrusion 940 can be less than 70%, specifically less than 50%, and more specifically less than 20% of the surface area of the second side or second surface 920.

The contact protrusion 940 can act as a spacer. The reduced contact area provided by the contact protrusion 940 facilitates a thermal expansion of the conductive sheet. The larger area of the second side or second surface 920 allows for a coverage of the through holes in the conductive sheet.

According to some embodiments, the mounting device 900 can have a roughened surface, similarly as described with respect to the one or more conductive sheets. In particular, the first side or first surface 910 can be a roughened surface to avoid deposit flaking. In some implementations, the first side or first surface 910 is coated with a rough surface coating or adhesive coating for better adhesion. According to some embodiments, the first side or first surface 910 could be coated with at least one of a dielectric coating and the rough surface coating to avoid arcing. For example, the dielectric coating can be selected from the group consisting of Al₂O₃, SiO₂, and YSZ (yttria-stabilized zirconia).

In some implementations, a material of the mounting device 900 is selected from the group consisting of SuS material, plastic, polymer material, metal, aluminum, and stainless steel.

During use in the sputter deposition chamber, deposition material can be deposited on the mounting devices 900 and cover, for example, the first side. In some implementations, the mounting device 900 can be reusable. As an example, chemical cleaning and/or sandblasting can be employed to remove the deposition material from the mounting device 900. In other implementations, the mounting device 900 can be disposable.

FIG. 10 shows a flow chart of a method 1000 for providing an electrical shielding in a sputter deposition chamber according to embodiments described herein. The method 1000 can utilize the shielding device and the system according to the embodiments described herein.

The method includes, in block 1100, a providing of an equipotential surface along a processing region and/or a substrate transportation path in the sputter deposition chamber using one or more conductive sheets detachably mounted on a frame assembly. In some implementations, the method includes in block 1200 a conducting of a sputter deposition process to form a material layer on the substrate. Sputter deposition process can be an RF sputter deposition process.

According to embodiments described herein, the method for providing an electrical shielding in a sputter deposition chamber can be conducted using computer programs, software, computer software products and the interrelated controllers, which can have a CPU, a memory, a user interface, and input and output devices being in communication with the corresponding components of the apparatus for processing a large area substrate.

The present disclosure provides an aligned shielding device, such as a back wall shielding, for a sputter deposition chamber. The shielding device can provide for an improved process stability and process efficiency and homogeneous film deposition. In particular, spatial RF potential differences can be minimized. The occurrence of least one of arcing, parasitic plasmas and crazing phenomena can be reduced or even avoided. The shielding is aligned along one geometrical line within an in-line sputter system, such as an in-line RF sputter system, to provide for a flat equipotential surface or area. Volumes for RF wave penetration are avoided or sealed using a mesh structure allowing for evacuation of the volumes. Particle generation due to material deposited on the shielding can be reduced or even avoided, and a PM (preventive maintenance) frequency can be reduced. A high system uptime can be provided. The exchangeable or disposable shields, such as disposable back-wall shields, allow for a facilitated maintenance and/or replacement. Cost of ownership can be reduced. A time for maintenance and/or replacement of the exchangeable or disposable shields can be reduced. The shielding device can be DC grounded. An RF-current return support or path can be included in the shielding device. Process stability can be improved.

While the foregoing is directed to embodiments of the disclosure, other and further embodiments of the disclosure may be devised without departing from the basic scope thereof, and the scope thereof is determined by the claims that follow.

1. System configured for sputter deposition on a substrate, comprising:
a sputter deposition chamber having a processing zone;
one or more sputter deposition sources arranged at a first side of the processing zone; and
a shielding device arranged at a second side of the processing zone, wherein the shielding device includes a frame assembly mounted to the sputter deposition chamber and one or more conductive sheets detachably mounted on the frame assembly, wherein the one or more conductive sheets provide a surface arranged along the processing zone.

2. The system of claim 1, wherein the one or more conductive sheets are configured to provide an equipotential surface.

3. The system of claim 1, further including one or more grounding devices configured to ground at least one of the frame assembly and the one or more conductive sheets.

4. The system of claim 3, wherein the grounding device includes a connection device and a connection line, and wherein the connection device is configured to connect the connection line to the shielding device.

5. The system of claim 1, wherein the one or more conductive sheets have a roughened surface.

6. The system of claim 1, wherein the one or more conductive sheets have a thickness of less than 3 mm.

7. The system of claim 1, wherein a material of the one or more conductive sheets is selected from the group consisting of aluminum, copper, steel, titanium and any combination thereof.

8. Shielding device for a sputter deposition chamber, comprising:
a frame assembly configured to be mounted to the sputter deposition chamber and along a processing zone in the sputter deposition chamber; and
one or more conductive sheets detachably mounted on the frame assembly, wherein the one or more conductive sheets are configured to face towards the processing zone.

9. The shielding device of claim 8, wherein the frame assembly includes a base frame connectable to the sputter deposition chamber.

10. The shielding device of claim 8, wherein the frame assembly includes a mounting frame having a mounting surface.

11. The shielding device of claim 8, wherein the frame assembly includes one or more side frame elements.

12. The shielding device of claim 8, wherein the frame assembly includes a conductive mesh provided at at least one of a top side and a bottom side of the frame assembly.

13. The shielding device of claim 8, further including one or more mounting devices configured to mount the one or more conductive sheets to the frame assembly.

14. The system of claim 1, wherein the shielding device is configured according to claim 8.

15. Method for providing an electrical shielding in a sputter deposition chamber, comprising:
providing an equipotential surface along a processing zone in the sputter deposition chamber using one or more conductive sheets detachably mounted on a frame assembly.

16. The system of claim 1, wherein the one or more conductive sheets are at least partially coated.

17. The system of claim 5, wherein the one or more conductive sheets are at least partially coated.

18. The shielding device of claim 10, wherein the one or more conductive sheets are detachably mounted on the mounting surface.

19. The shielding device of claim 14, wherein the one or more side frame elements provide a lateral termination of the one or more conductive sheets.
